(19) United States
(12) Patent Application Publication
(10) Pub. No.: US 2021/0072046 A1
(43) Pub. Date: Mar. 11, 2021

(54) SENSOR DEVICE WITH A CAPACITIVE SENSOR FOR MOTOR VEHICLES

(71) Applicant: HUF HÜLSBECK & FÜRST GMBH & CO. KG, Velbert (DE)

(72) Inventors: Peter Van Gastel, Solingen (DE); Michael Elssner, Moenchengladbach (DE); Andreas Gornik, Bochum (DE); Michael Kalesse, Ratingen (DE)

(73) Assignee: Huf Huelsbeck & Fuerst GmbH & Co. KG, Velbert (DE)

(21) Appl. No.: 16/772,442

(22) PCT Filed: Aug. 30, 2018
(86) PCT No.: PCT/EP2018/073394

§ 371 Date: Jun. 12, 2020

(30) Foreign Application Priority Data
Dec. 18, 2017 (DE) 10 2017 130 379.0

(51) Int. Cl. G01D 5/24; E05B 85/10; E05B 81/76; H03K 17/955

(52) U.S. Cl. CPC G01D 5/24; E05B 85/10; E05Y 2900/531; H03K 17/955; E05Y 2400/86; E05B 81/77

(57) ABSTRACT

A sensor device for a motor vehicle for detecting an operation by a user, including at least one capacitive sensor which has a sensor electrode, which is coupled to a control and evaluation circuit. The sensor electrode has a primary detection section which extends adjacent to a detection region into which a body part of a user is moved for operation purposes. The sensor electrode is accommodated in a housing which runs, in sections, between the sensor electrode and the detection region. The sensor electrode is provided, in the region of the primary detection section, for increasing the electrical field in sections, with recesses and/or openings which are delimited by edges, so that a length at the limiting edges, which length is increased in relation to a continuous electrode area, is present in the primary detection section.

The invention relates to a sensor device having at least one capacitive sensor. Sensor devices of this type are used at various points in motor vehicles, for example in the region of the door handles, tailgates, or the instruments in the interior.

The capacitive sensor electrode of such a sensor assembly is coupled to a control and evaluation circuit. The sensor electrode has at least one primary detection section that extends adjacent to a detection region. Body parts that a user moves into this detection region for operation purposes are detected in a detection region. For this purpose, the sensor electrode is accommodated in a housing which runs at least in sections between the sensor electrode and the detection region and thus removes the sensor electrode from direct access and contacting by the user, and also protects against other environmental influences.

Such sensor devices with integrated capacitive sensors are known in the art; in particular their use in exterior door handles of motor vehicles is widespread. For example, DE 196 17 038 A1 discloses a door handle having capacitive sensors in order to detect a proximity of a potential operator. The control and evaluation circuit coupled to the at least one sensor electrode measures a capacitance of the sensor electrode with respect to ground. By approaching the hand or another body part of an operator from outside the detection region into the detection region, the capacitance of the electrode is changed in relation to ground, and this is detected by the control and evaluation circuit. Depending on the signal detected, a function can be triggered in the vehicle.

The function of a capacitive sensor and a control and evaluation circuit are not explained in the context of this application, since they are generally known. In particular, circuits for frequently reloading the sensor electrode are known, wherein charge durations or amounts of charge are detected, from which the capacitance of a sensor electrode can be deduced.

With regard to the classic consideration of the capacitance of the plate capacitor, the sensitivity of the sensor electrodes is primarily dependent on the detection area and on the distance of the detection area from the detection region.

It is always a goal of the capacitive sensor technology to provide the highest possible sensitivity with the smallest and lightest possible sensor electrodes.

The object of the invention is therefore to improve the sensitivity of sensor electrodes without negatively influencing the electrode size.

This object is achieved by a sensor device having the features of claim 1 and a sensor device having the features of claim 7.

According to claim 1, a sensor device of the type mentioned in the introduction has recesses and/or openings in the region of its primary detection section which are delimited by edges. These recesses and/or openings are accordingly arranged in such a way that their delimiting edges lie in the primary detection section and thus an increased number or length of edges is formed in this primary detection section compared to a continuous electrode area.

The primary detection section is the extension region of the sensor electrode, which is designed to form the sensed electrical field that can be changed by user proximity in the detection region. In addition, the sensor electrode can have, for example, feed lines and shielded areas, which are conductively connected, but do not contribute to the detection capability to a technically relevant extent. The definition of the primary detection section thus depends on the professional design of the sensor assembly and is also dependent on the voltage applied and the housing geometry and other components. At least the section of the electrode that is spatially closest to the detection region is part of the primary detection section.

It is known in physics that in the case of conductive objects which are at a predetermined potential, the field lines are increased or compressed at edges, tips and corners. The smaller the radius of curvature of such an edge, tip, or corner, the greater the field increase. This effect is used for example in corona discharges. It has been found that the targeted arrangement of edges, tips or corners in the primary detection section of a sensor electrode has a favorable effect with regard to the sensitivity of the sensor electrode. If such edges, corners or tips are in the primary detection section, a smaller electrode area is sufficient to be able to provide identical sensitivities in comparison to continuous electrodes.

In order to achieve the corresponding field increase effects, radii of curvature must be selected which clearly favor the effect of the field increase. These are regularly radii of curvature well below 1 mm; regularly the radii of curvature should be less than 100 μm and can, for example in the formation of tips, burrs, corners, or roughness, be significantly smaller than 10 μm and can certainly be in the range of nanometers.

It is therefore provided within the scope of the invention to form angular, in particular sharp-edged delimitations of the electrode or corresponding contours of the surface of the electrode in the primary detection section of the electrode. At these points, a field increase occurs, which favors the sensitivity of the electrode.

The edges, corners and tips are to be aligned in such a way that the field increase is directed in the direction of the detection region, in particular on the side of the sensor electrode facing the detection region.

The edges can be outer delimitations of the electrode; they can also be edges that delimit openings in the electrode, for example bores, punchings, embossings, or the like.

It is substantial that in the region of the primary detection section of the sensor electrode, the geometry, and surface design of the sensor electrode specifically cause field increases. This seems to contradict the fundamental endeavor to design components without sharp edges and without burrs if possible. According to this invention, however, correctly placed edges, burrs, and roughness in a corresponding form are favorable for the field increase and for improving the sensitivity.

Regarding an increased length at the delimiting edges in the primary detection section, a continuous electrode area is used as a comparison, the area of which covers and envelops the region of the primary detection section, wherein the recesses and/or openings according to the invention are spanned by the continuous electrode. For example, such an electrode according to the invention with an increased edge length can be formed by punching out, cutting out, or drilling out parts of the electrode area, wherein the edges of the respective recesses and/or openings are arranged in the primary detection section.

In a development of the invention, the sum of the length of all edges delimiting the primary detection section is at least 25% greater than the edge length of a rectangle enveloping the primary detection area.

In accordance with this exemplary embodiment, an electrode area is enlarged in terms of its edge length by cuts, notches, or bores in such a way that this edge length is at least 25% longer than in the case of a rectangular electrode which covers the primary detection section.

In a further embodiment of the invention, the sensor electrode is formed from a metallic flat material in the primary detection section.

Metallic flat materials are particularly easy to machine with regard to the possibility of forming openings and recesses and, moreover, can be brought into a desired shape for adaptation to a sensor assembly. Such flat materials can in particular be sheet metal, flat cast bodies, metallic layers on guide plates, or the like.

The manufacture of such sensor electrodes is particularly simple and, in addition to a cut to form edges, upstands and profiles can also be made, which further improve the field increase in these regions.

In a particularly preferred embodiment of the invention, the sensor electrode is formed in the primary detection section having two conductor structures which are spaced apart and are each delimited by edges. The spaced-apart conductor structures can be designed, for example, like parallel fingers or guide structures arranged next to one another.

It is particularly preferred if the spaced-apart conductor structures are connected in a fork-like manner by a common base section of the sensor electrode, wherein the base section extends at least partially outside the primary detection section.

Such a fork-like structure provides, in particular in the case of mechanically independent sensor electrodes, that is to say in particular sensor electrodes without an underlying carrier material, a mechanically stable design which is always aligned with respect to the conductor structures. Such a sensor electrode is easy to arrange and the conductors are correctly aligned with each other at all times. In these electrodes, the primary detection section is formed from sections of the two parallel conductor structures. The sensor electrode is thus arranged, for example, in such a way that an operator places a finger on a region of the housing; such that the finger spans the space between the conductor structures, and such that the edges delimiting the space lie under the finger. With regard to the specific design of the edges, a person skilled in the art can choose a method for manufacture which is matched to the electrode material and the processing options. However, it is particularly preferred if the radius of curvature in the region of the edges is less than 0.5 mm, preferably less than 0.1 mm, and in particular less than 50 μm. Smaller radii of curvature, for example in the nanometer range, are also possible with suitable methods.

Since the extent of the field increase in this region depends strongly on the radius of curvature, the aim should be to choose and design the radius of curvature as small as possible, insofar as this can be achieved with the technically accessible options. A radius of curvature of a few micrometers or even in the sub-micrometer range is generally desirable, but cannot be achieved with many electrode materials in view of their production or softness and the available processing steps. However, burrs achieved during cutting processes or punching processes can certainly achieve corresponding radii of curvature, wherein these burrs are then able to be left in a targeted manner in order to provide additional field increases.

According to a second aspect of the invention, the sensor device of the type mentioned in the introduction has tips and/or corners in the region of the primary detection section for increasing the electrical field in sections on the side facing the detection region. Tips and/or corners are to be understood as structures which are specifically designed for increasing the electrical field. In particular, the tips and/or corners are characterized by radii of curvature which are realized as small as possible, depending on the electrode material and available production means.

In a preferred embodiment of the invention, the sensor electrode is formed in the region of the primary detection section from a metallic flat material which has been roughened mechanically and/or thermally and/or by material application at least in regions to form tips and/or corners.

Mechanical means can be used to form the tips and/or corners in the primary detection section, in particular embossing means, cutting means, or machining methods which lift or deform material from the sensor electrode in the primary detection section in order to form tips and/or corners. As an alternative or in addition, thermal methods can be used, for example an electrode area can be melted on, in order to then pull threads or tips of the electrode material by pressing and lifting tools before the material cools down again.

Finally, it is also possible to provide the electrode area with a targeted application of material in order to apply corners, tips, or a generally greater roughness through this additional material. The material applied can be identical to the material of the electrode or another material. For example, metal colloids can be sprayed onto the surface with a conductive adhesion promoter in order to form tips or corners on the surface of the electrode through the colloids.

Again, the radius of curvature of the tips or corners should be made as small as possible in this region, but consideration must be given to the available production tools and materials. The tips or corners should have a maximum of a few 10 μm, preferably a few micrometers to sub-micrometer radii of curvature.

If the roughness of the sensor electrode is specifically increased in addition to or instead of the corners and tips, the sensitivity is also increased. For the definition of the roughness, reference is made to DIN EN ISO 4287 (edition 07-2010). According to this exemplary embodiment, the roughness of the electrode area is deliberately increased in comparison with conventional manufacturing methods and electrodes. If, for example, a sensor electrode is created on a circuit board using a wet chemical method, it can be assumed that surface chemical topographies with Ra=0.2-0.5 μm and Rz=2.5-5 μm occur (depending on the etching rate) in commercially available chemical micro-etching methods (for the definition of the parameters see below and definition of the named DIN EN ISO 4287). According to the preferred embodiment, sections or regions of the detection section of the sensor electrode are equipped with larger values of the roughness depth or the average roughness value in comparison with these values during manufacture or by post-processing. This increases the surface region of the sensor electrode and increases the density of the deformations with tips or corners on the surface, which leads to an improved sensitivity.

The invention will now be explained in more detail with reference to the accompanying drawings.

FIG. 1 shows schematically the arrangement of a sensor device in a vehicle door handle according to the prior art;

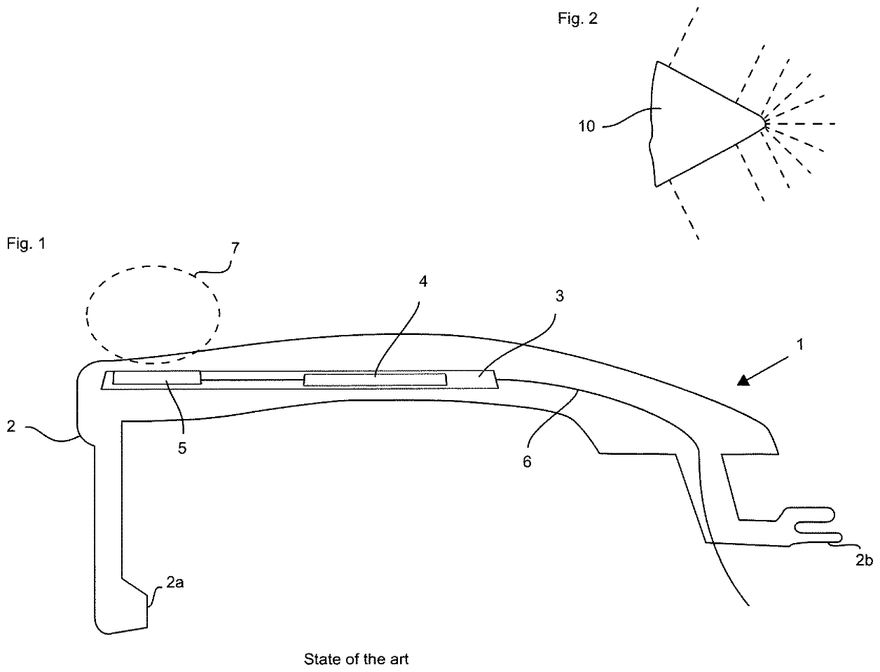

FIG. 2 shows schematically the effect of the field increase at an electrode tip;

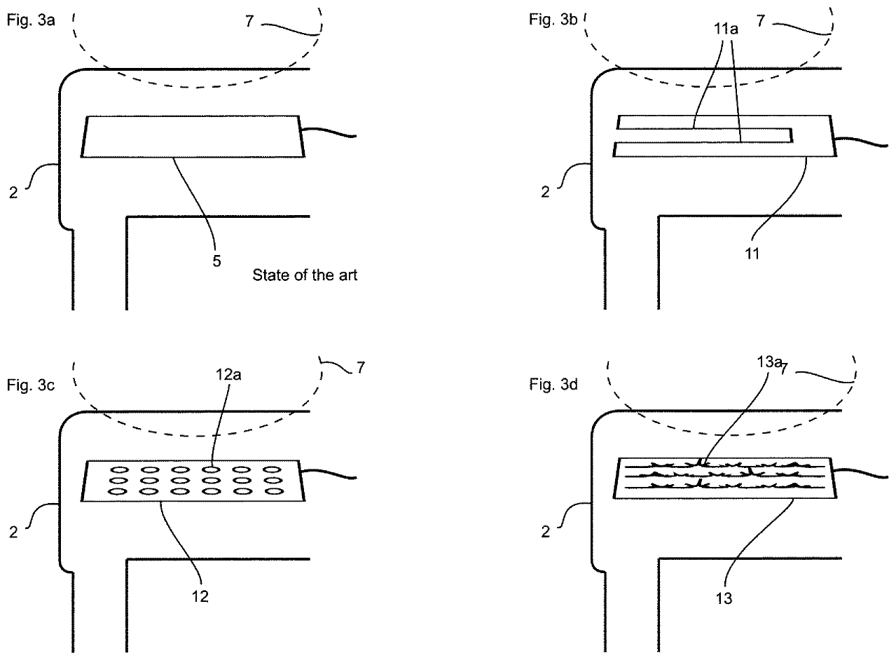

FIG. 3a shows schematically the arrangement of a sensor electrode according to the prior art in the door handle;

FIG. 3b shows schematically the arrangement of a sensor electrode according to a first exemplary embodiment of the invention in a door handle;

FIG. 3c shows schematically the arrangement of a sensor electrode according to a second exemplary embodiment of the invention in a door handle; and

FIG. 3d shows schematically the arrangement of a sensor electrode according to a third exemplary embodiment of the invention in a door handle;

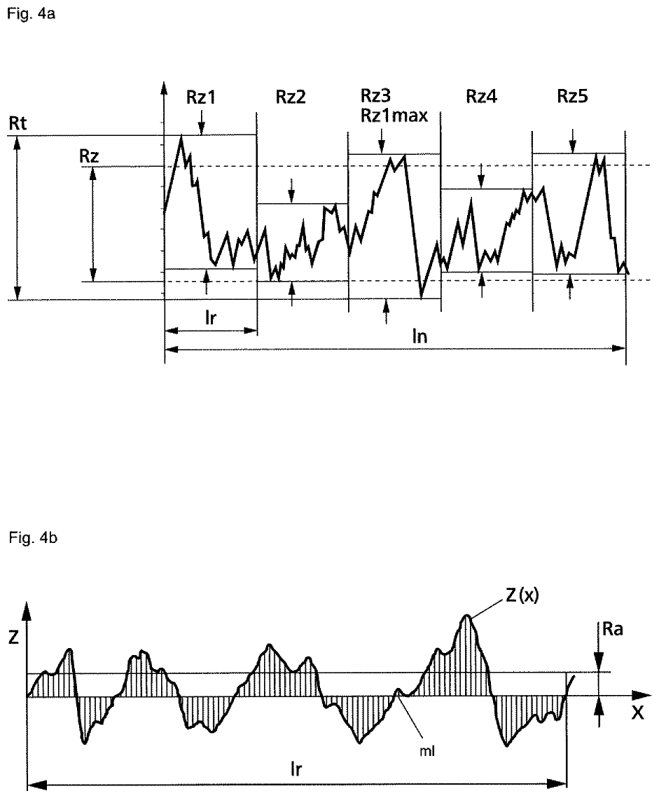

FIG. 4a shows schematically the definitions of some roughness parameters according to DIN EN ISO 4287;

FIG. 4b shows schematically the definitions of a roughness parameter according to DIN EN ISO 4287;

FIG. 1 shows a motor vehicle door handle 1 which has a housing 2 on which mechanical coupling elements 2a and 2b are arranged. The mechanical coupling elements 2a and 2b protrude through a door panel into the interior of a door and ensure a mechanical operative connection of the door handle having an operational structure arranged in the door (not shown).

The housing 2 accommodates a circuit board 3 in the region of the handle of the door handle, on which a control and evaluation circuit 4, and a sensor electrode 5 are mounted. The electronics on the circuit board 3 can be coupled to a central control device in the vehicle by means of a line or a cable harness 6.

The control and evaluation circuit 4 controls the sensor electrode 5 and supplies it with voltage. This has the effect that an electrical field is built up by the sensor electrode 5, which extends through a detection region 7, which is arranged outside the housing 2 and is accessible to a user in the room. If a user moves his hand or his finger in the detection region 7, the capacitance of the sensor electrode 5 changes as a result, which is detected by the control and evaluation circuit 4.

As described above, various control and evaluation circuits for capacitive sensor electrodes are known and described in the prior art. The size and extent of the detection region 7 are influenced, in particular, by the area of the sensor electrode 5 and its orientation, as well as the voltage applied and the associated measuring method of the control and evaluation circuit 4.

A flat sensor electrode according to the prior art is shown in the sensor electrode in FIG. 1.

The invention makes use of the effect of a field increase at edges, tips, and corners in electrical fields. FIG. 2 schematically shows a tip of a sensor electrode 10 to which a voltage has been applied. A counter electrode is not shown in this illustration, since it is not necessary for understanding. When a voltage is applied to a conductive electrode 10, the surface of the electrode is an equipotential area. In the region of tips, corners, edges, and general areas having a small radius of curvature, there is a so-called field increase, represented by field lines that are closer together. This effect is well known and studied physically and is used in various applications.

If the orientation of the electrode from FIG. 2 is chosen such that the region of the field increase is aligned with the detection region, an increase in the sensitivity of the sensor electrode can be achieved without requiring a significant increase in the entire electrode area.

FIG. 3a shows an example of the arrangement of the sensor electrode 5 from FIG. 1 according to the prior art in the door handle 2 in a detail enlargement. The electrode is arranged flat, the perspective in FIGS. 3a to 3d indicating that the flat surface of the electrode is oriented perpendicular to the detection region 7.

This type of flat electrode as in FIG. 3a occurs in various rectangular or round dimensions in the prior art in numerous capacitive sensor devices. It defines a reference variable against which the invention is distinguished. According to the invention, structures are created on the electrode which lead to a field increase.

FIG. 3b shows a first exemplary embodiment for improving the sensitivity while reducing the electrode area.

In FIG. 3b, a U-shaped electrode is arranged in the door handle, wherein the areal extension of the electrode is here also perpendicular to the detection region.

Compared to the electrode from FIG. 3a, the edge length in the electrode region is increased according to the invention in that two electrode legs are guided at a distance from one another. At these edges, which are designed with the smallest possible radius of curvature, the field increase occurs, and the sensitivity in this electrode region is increased. Although the area of the electrode is reduced compared to the electrode from FIG. 3a, measurements have shown that an increased sensitivity can be determined when an identical object is approached identically. For this purpose, in a test setup, grounded metal cuboids were placed at identical distances both with flat electrodes as in FIG. 3a and with fork-like electrodes as in FIG. 3b. The corresponding signal response and capacitive change was reproducibly higher in the electrode arrangement from FIG. 3b, although less electrode material is used. The detection region extends above the two legs of the electrode, but in particular also extends over the gap in between. A field increase at the edges 11a overcompensates for the effect of the missing electrode area. The effect of the field increase is initially dependent on the edges, so the gap can be chosen to be very narrow. On the other hand, electrode material is saved due to the gap formation. The ratio of electrode area, edge length, and gap dimensions can be optimized in simple measurements to ensure the desired sensitivity.

FIG. 3c shows a second embodiment of the invention, in which the edge length is increased by milling or drilling in the surface of the electrode 12. These can be through openings through the entire electrode material, which are delimited by edges 12a; alternatively, blind openings can also be made in the surface of the electrode 12 to form edges. It is entirely possible to design the delimitations of the respective openings, millings, or bores in such a way that burrs remain in the direction of the detection. For example, electrode sheets can be punched or drilled from the rear, such that burrs protrude from the edges of the holes in the direction of detection. Such burrs and edges significantly improve the sensitivity of the electrode, since significant field increases are formed on them, at the same time saving electrode material.

FIG. 3d shows a sensor electrode 13 according to a third exemplary embodiment of the invention. Surface roughness, tips, and corners are applied in a targeted manner to the electrode area 13. This can be done by a cutting method, for example a targeted roughening of the surface by roughing or by combined thermal, mechanical treatment. Finally, such surface roughness can also follow by applying conductive and curable dry materials or colloid solutions. It is substantial that the surface is roughened in a targeted manner compared to a conventional surface or is manufactured with corresponding edges, corners, or tips.

It is possible to combine the different designs of the different exemplary embodiments in order to further increase the effect. For example, the electrode 11 from the first exemplary embodiment or the electrode 12 from the second exemplary embodiment can be provided with a corresponding surface roughness.

FIGS. 4a and 4b explain the roughness parameters to which reference is made in the claims and which correspond to the definitions of DIN EN ISO 4287.

A measuring section In can be divided into several individual measuring sections Ir. The lines shown in FIGS. 4a and 4b show a surface profile along the measuring section In.

FIG. 4a shows that an average roughness depth Rz can be determined for the measuring section In, which is obtained as the mean value from the Rz values of the individual sections contained.

The characteristic variable Ra shown in FIG. 4b denotes the arithmetic mean roughness value, which is the average deviation of the profile values from the center line ml.

For further definition and description of measurement of the parameters, reference is made to DIN EN ISO 4287.

If the roughness of the electrode area is mentioned in the foregoing, this refers to a structural design of the electrode area which represents a greater roughness according to the parameters mentioned than is provided in the usual manufacturing methods of, for example, conductor tracks. The roughness is therefore increased in a targeted manner compared to conventional manufacturing processes. As described above, standard chemical micro-etching methods have surface topographies with Ra 0.2-0.5 μm and Rz=2.5-5 μm. According to the invention, sections or regions of the detection section of the sensor electrode can be equipped with larger values of the roughness depth or the mean roughness value during manufacture or by post-processing. This increases the surface region of the sensor electrode and increases the density of the deformations with tips or corners on the surface, which leads to an improved sensitivity.

1. Sensor device for a motor vehicle for detecting an operation by a user, comprising at least one capacitive sensor which has a sensor electrode,
the sensor electrode being coupled to a control and evaluation circuit,
wherein the sensor electrode has a primary detection section which extends adjacent to a detection region into which a body part of a user is moved for operation purposes,
wherein the sensor electrode is accommodated in a housing which runs, in sections, between the sensor electrode and the detection region,
wherein
the sensor electrode is provided, in the region of the primary detection section, for increasing the electrical field in sections, with recesses and/or openings which are delimited by edges, so that a length at the limiting edges, which length is increased in relation to a continuous electrode area, is present in the primary detection section.

2. Sensor device according to claim 1, wherein the sum of the lengths of all edges delimiting the primary detection section is at least 25% greater than the edge length of a rectangle enveloping the primary detection area.

3. Sensor device according to claim 1, wherein the sensor electrode is made of a metallic flat material in the primary detection section.

4. Sensor device according to claim 1, wherein the sensor electrode has two or more spaced-apart conductor structures delimited by edges in the primary detection section.

5. Sensor device according to claim 4, wherein the spaced conductor structures are connected in a fork-like manner by a common base section of the sensor electrode, wherein the base section extends at least partially outside the primary detection section.

6. Sensor device according to claim 1, wherein a radius of curvature of the electrode material in the region of at least part of the edges in the primary detection section and in a direction transverse to the edge is less than 0.5 mm.

7. Sensor device for a motor vehicle for detecting an operation by a user, with at least one capacitive sensor having a sensor electrode,
wherein the sensor electrode is coupled to a control and evaluation circuit,
wherein the sensor electrode has at least one primary detection section which extends along a detection region into which a body part of a user is moved for operation purposes,
wherein the sensor electrode is accommodated in a housing which runs, in sections, between the sensor electrode and the detection region,
wherein a primary detection area is determined by a projection of the primary detection section in the direction of the detection region,
wherein
the sensor electrode is formed in the region of the primary detection section for increasing the electrical field in sections having surface deformations facing the detection region in the form of tips and/or corners and/or roughness.

8. Sensor device according to claim 7, wherein the sensor electrode is made of a metallic flat material in the primary detection section, which has been roughened mechanically and/or thermally and/or by material application at least in regions to form tips and/or corners.

9. Sensor device according to claim 1, wherein a radius of curvature of the electrode material in the region of the tips and/or corners is less than 0.5 mm.

10. Sensor device according to claim 7, wherein the primary detection section has a roughness in the region of the tips and/or corners, having a mean roughness value Ra>0.5 μm and/or an average roughness depth Rz>5 μm according to DIN ISO 4287.

11. Sensor device according to claim 10, wherein the primary detection section has a roughness in the region of the tips and/or corners, having a mean roughness value Ra>1 μm and/or an average roughness depth Rz>10 μm according to DIN ISO 4287.

12. Sensor device according to claim 6, wherein the radius of curvature is less than 0.1 mm.

13. Sensor device according to claim 6, wherein the radius of curvature is less than 50 μm.

14. Sensor device according to claim 9, wherein the radius of curvature is less than 0.1 mm.

15. Sensor device according to claim 9, wherein the radius of curvature is less than 50 μm.
